(19) United States
(12) Patent Application Publication
(10) Pub. No.: US 2026/0370239 A1
(43) Pub. Date: Nov. 19, 2026

(54) PERFORMANCE-EFFICIENT ENCODING FOR ZSTANDARD COMPRESSION

(71) Applicant: XILINX, INC., San Jose, CA (US)

(72) Inventors: Robert Bellarmin SUSAI, Hyderabad (IN); Durga Neeraj KOIDALA, Hyderabad (IN); Rohit Kumar SHARMA, Hyderabad (IN); Vishnu CHEERAKODA, Hyderabad (IN)

(21) Appl. No.: 19/212,314

(22) Filed: May 19, 2025

(51) Int. Cl. H03M 7/30; H03M 7/40; H03M 7/42

(52) U.S. Cl. CPC H03M 7/6011; H03M 7/3088; H03M 7/405; H03M 7/3086; H03M 7/42

(57) ABSTRACT

Performance-efficient encoding for Zstandard compression using a content-addressable memory (CAM)-based encoder circuit that includes multiple CAM circuits, and write logic to write entries of a finite state entropy (FSE) table to the CAM circuits, where each entry of the FSE table includes a FSE state, a symbol, bits, and a baseline. Search logic simultaneously searches the CAM circuits based on a current state of the FSE table and the symbol, and outputs results of the search, during a clock cycle. Decoder logic selects results of one of the CAM circuits based on the bits, the baseline, and the FSE states of the respective results, during the clock cycle. A latch outputs the selected results in a subsequent clock cycle, where the output include an indication of a CAM hit, a next FSE table state, a bit value, and a length of the bit value.

### TECHNICAL FIELD

Examples of the present disclosure generally relate to encoding and, more particularly, to performance-efficient encoding for Zstandard compression.

### BACKGROUND

Zstandard is a lossless data compression algorithm that combines a dictionary-matching stage (e.g., LZ77) with a large search window, and uses Huffman coding with a finite state entropy (FSE) coding stage. Software-based encoding schemes are inefficient in terms of performance, and are time consuming.

### SUMMARY

Techniques for performance-efficient encoding for Zstandard compression are described. One example is an integrated circuit device that includes a content addressable memory (CAM)-based encoder circuit that includes multiple CAM circuits, write logic to write entries of a finite state entropy (FSE) table to the CAM circuits, where entries of the FSE table include a FSE state, a symbol, bits, and a baseline, search logic to simultaneously search the CAM circuits based on a current state of the FSE table and the symbol, and to output results of the search, during a clock cycle, decoder logic to select results of one of the CAM circuits based on the bits, the baseline, and the FSE states of the respective results, during the clock cycle, and a latch to output the selected results in a subsequent clock cycle, where the selected results include an indication of a CAM hit, a next FSE table state, a bit value, and a length of the bit value.

Another example described herein is system that includes a host processor and memory encoded with instructions to cause the host processor to output data, and a content-addressable memory (CAM)-based encoder circuit to compress the data, where the CAM-based encoder circuit includes multiple CAM circuits, write logic to write entries of a finite state entropy (FSE) table to the CAM circuits, where entries of the FSE table include a FSE state, a symbol, bits, and a baseline, search logic to simultaneously search the CAM circuits based on a current state of the FSE table and the symbol, and to output results of the search, during a clock cycle, decoder logic to select results of one of the CAM circuits based on the bits, the baseline, and the FSE states of the respective results, during the clock cycle, and a latch to output the selected results in a subsequent clock cycle, wherein the selected results include an indication of a CAM hit, a next FSE table state, a bit value, and a length of the bit value.

Another example described herein is method that includes writing entries of a finite state entropy (FSE) table to a set of content addressable memory (CAM) circuits, where entries of the FSE table include a FSE state, a symbol, bits, and a baseline, simultaneously searching the CAM circuits based on a current state of the FSE table and the symbol, and outputting results of the search, during a clock cycle, selecting results of one of the CAM circuits based on the bits, the baseline, and the FSE states of the respective results, during the clock cycle, and outputting the selected results in a subsequent clock cycle, where the selected results include an indication of a CAM hit, a next FSE table state, a bit value, and a length of the bit value.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 depicts a data compression system, according to an embodiment.

FIG. 2 depicts data compression system, according to an embodiment.

FIG. 3A depicts an example of an end portion of a Huffman tree description, according to an embodiment.

FIG. 3B depicts a literal finite state entropy (FSE) table, according to an embodiment.

FIG. 4 depicts a ternary content-addressable memory (TCAM) based encoder circuit, according to an embodiment.

FIG. 5 depicts the TCAM-based encoder circuit, according to an embodiment.

FIG. 6 depicts a method of dictionary-based compression, according to an embodiment.

FIG. 7 depicts a method of encoding weights based on FSE tables, according to an embodiment.

FIG. 8 depicts an integrated circuit device that includes a data compression system, according to an embodiment.

To facilitate understanding, identical reference numerals have been used, where possible, to designate identical elements that are common to the figures. It is contemplated that elements of one example may be beneficially incorporated in other examples.

### DETAILED DESCRIPTION

Embodiments herein describe performance-efficient encoding for Zstandard compression.

The Zstandard encoding algorithm represents a LZ77 output as a series of literals and sequences. The Zstandard encoding algorithm uses Huffman codes along with finite state entropy (FSE) codes to represent the compressed data.

The Zstandard encoding of Huffman tree descriptions of literals and sequences includes traversing and carrying out a search across the FSE table. Since the size of the FSE table can range up to a maximum of 512, other search methods (e.g., instruction/processor-based methods) are inefficient in terms of performance, and are time consuming. In a case where Zstandard is used to compress larger file sizes, there may be more sequences, and increasing the search by even one more clock cycle would reduce overall performance.

Embodiments herein describe a ternary content addressable memory (TCAM) integrated solution that encodes Huffman tree descriptions of literals and sequences by traversing through a FSE table, one per each clock cycle, and completes a search within one clock cycle, which reduces the encoding time relative to other approaches.

Embodiments herein may be used while implementing the encoding of Huffman tree description of literals and sequences using the FSE table in Zstandard 0.4.0.

Embodiments herein include a TCAM structure that stores the FSE table, a register memory that stores the Huffman symbols for literals, control logic that handles the processing, and a buffer that accumulate the encoded Huffman tree descriptions.

The control logic reads the Huffman symbols from the memory in a reverse order and sends it to the TCAM structure as inputs. The current state and next symbol value are provided to the TCAM structure as inputs. The TCAM structure traverses through the FSE table and outputs a TCAM hit, next state, the bits length, and its value. The value is encoded in the bitstream and can be used to jump from the current state to the next state.

The TCAM structure may output the value to be encoded for each Huffman symbol of a literal in every clock cycle, thereby increasing the performance of the overall design. A similar approach may be used for encoding the sequences, which are also a part of the Zstandard compressed frame.

Embodiments herein are scalable for encoding Zstandard sequences as well. Embodiments herein provide a way to achieve higher performance with optimal use of resources.

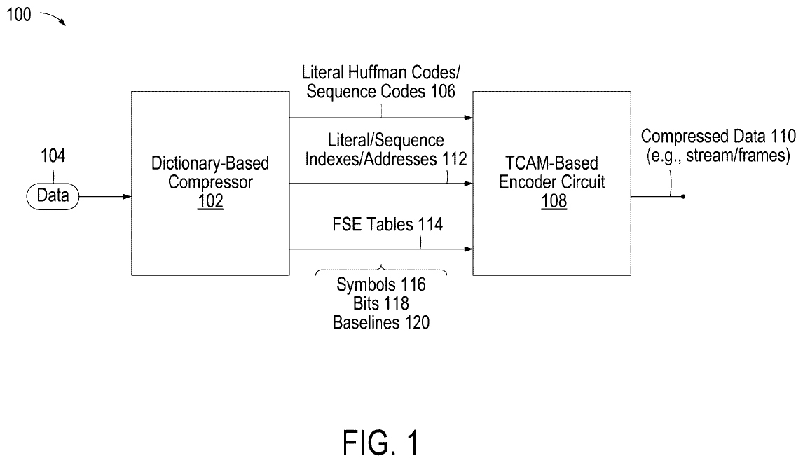

FIG. 1 depicts a data compression system (system) 100, according to an embodiment. System 100 includes a dictionary-based compressor (compressor) 102 that compresses data 104 (e.g., blocks of data or a data stream) to provide literal Huffman codes/sequence codes 106, indexes/addresses 112, and a finite state entropy (FSE) table 114. Compressor 102 may include circuitry (e.g., combinational logic and/or sequential logic) and/or a processor and memory encoded with instructions for execution by the processor.

System 100 further includes a ternary content-addressable memory (TCAM) based encoder circuit 108 that encodes literal Huffman codes/sequence codes 106 to provide compressed data 110 (e.g., Zstandard frames) based on FSE table 114. In the example of FIG. 1, FSE table 114 includes symbols 116, bits 118, and baselines 120.

TCAM-based encoder circuit 108 encodes literal Huffman codes/sequence codes 106 for sequence symbols 212 and literal symbols 208 of one or more blocks of data 104 to provide compressed data 110 (e.g., Zstandard frames).

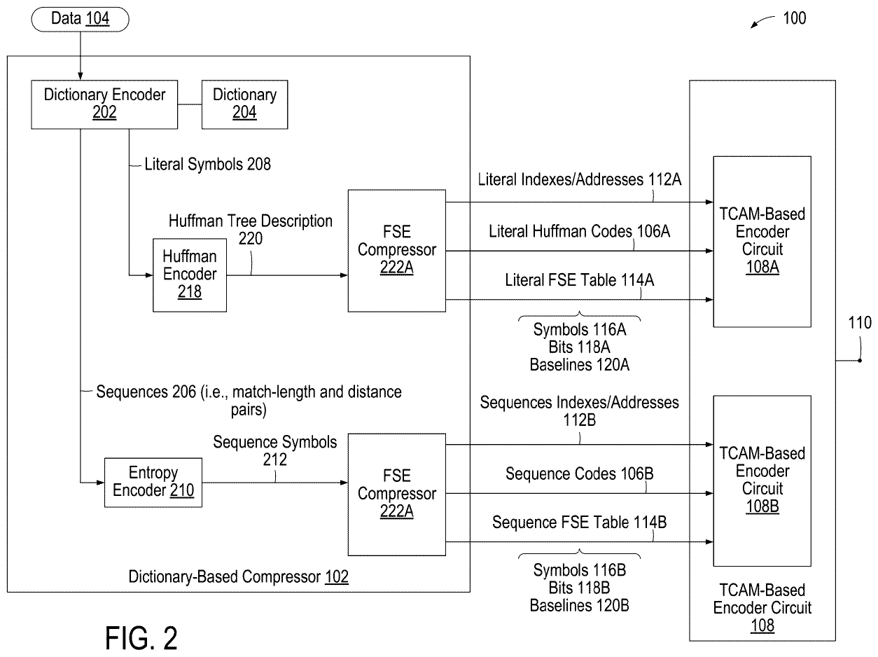

Compressor 102 may represent a Zstandard based compressor, such as described below with reference to FIG. 2. Compressor 102 is not, however, limited to a Zstandard-based compressor. FIG. 2 depicts system 100, according to an embodiment. In the example of FIG. 2, compressor 102 includes a dictionary encoder 202 (e.g., a LZ77 encoder or an LZ78 encoder), that searches a dictionary 204 based on data 104.

Dictionary encoder 202 may maintain a sliding window of data 104 within dictionary 204 (e.g., the last 2 KB, 4 KB, or 32 KB of data 104). A larger sliding window improves the chances of finding a match and for finding longer matches. Dictionary encoder 202 may search dictionary 204 based on symbols of data 104.

Dictionary encoder 202 encodes a match as a match-length and distance pair, which may be collectively referred to as a sequence 206. A match-length and distance pair may be interpreted as, “each of the next x characters is equal to x characters exactly y characters behind it in the uncompressed stream (i.e., data 104),” where x represents the match length and y represents the distance. The distance may also be referred to as an offset. If dictionary encoder 202 does not identify a match for a portion of data 104 within dictionary 204, dictionary encoder 202 outputs the portion of data 104 as a literal symbol 208.

Compressor 102 further includes a Huffman encoder 218 that encodes literal symbols 208 as a Huffman tree descriptions 220, and an entropy encoder 210 that encodes sequences 206 as sequence symbols 212.

Compressor 102 further includes a first finite-state entropy (FSE) compressor 222A that performs FSE compression of Huffman bits of Huffman tree description 220, to provide a literals FSE table 114A. FSE encoding/decoding involves a state that is carried over between symbols, and FSE compressor 222A performs FSE compression on pairs of Huffman tree descriptions 220, where bits 118A and baselines 120A specify a jump between the pair of Huffman tree descriptions 220 of literals. In an example, FSE compressor 222A converts numbers of Huffman bits of Huffman tree descriptions 220 to weights, determines a probability distribution of the weights for the block of data 104, and encodes the probabilities as literal FSE table 114A. FSE compressor 222A may normalize the probability distribution such that weights may be represented with fewer bits

Compressor 102 further includes a second finite-state entropy (FSE) compressor 222B that performs FSE compression on sequence symbols 212 of a block of data 104 to provide a sequence FSE table 114B. As described above, FSE encoding/decoding involves a state that is carried over between symbols, and FSE compressor 222B performs FSE compression on pairs of sequence symbols 212, where bits 118B and baselines 120B specify a jump between the pair of sequence symbols 212. FSE compressor 222B may determine an offset, match length, and literal length based on the match-length and distance pairs of sequences 206. In an example, FSE compressor 222B converts sequence symbols 212 to weights, determines a probability distribution of the weights for the block of data 104, and encodes the probabilities as sequence FSE table 114B. FSE compressor 222B may normalize the probability distribution such that weights may be represented with fewer bits.

In the example of FIG. 2, TCAM-based encoder circuit 108 includes a TCAM-based encoder circuit 108A for literals, and a TCAM-based encoder circuit 108B for sequences. In another example, TCAM-based encoder circuit 108 may use a single TCAM-based encoder circuit 108 to processes sequences and literals.

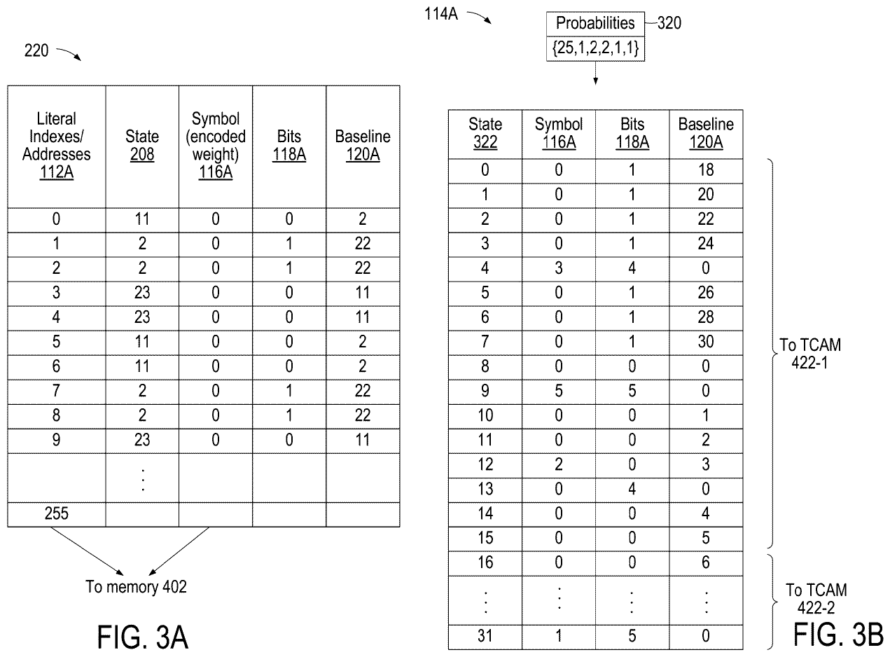

FIG. 3A depicts an example of an end portion of Huffman tree description 220, according to an embodiment. FIG. 3B depicts literal FSE table 114A, according to an embodiment. In the example of FIG. 3B, literal FSE table 114A is based on probabilities 320. Further in FIG. 3B, literals FSE table 114A includes FSE states 322 (i.e., FSE table indexes or addresses). Further in FIG. 3B, literals FSE table 114A includes 32 entries. Literals FSE table 114A is not limited to 32 entries.

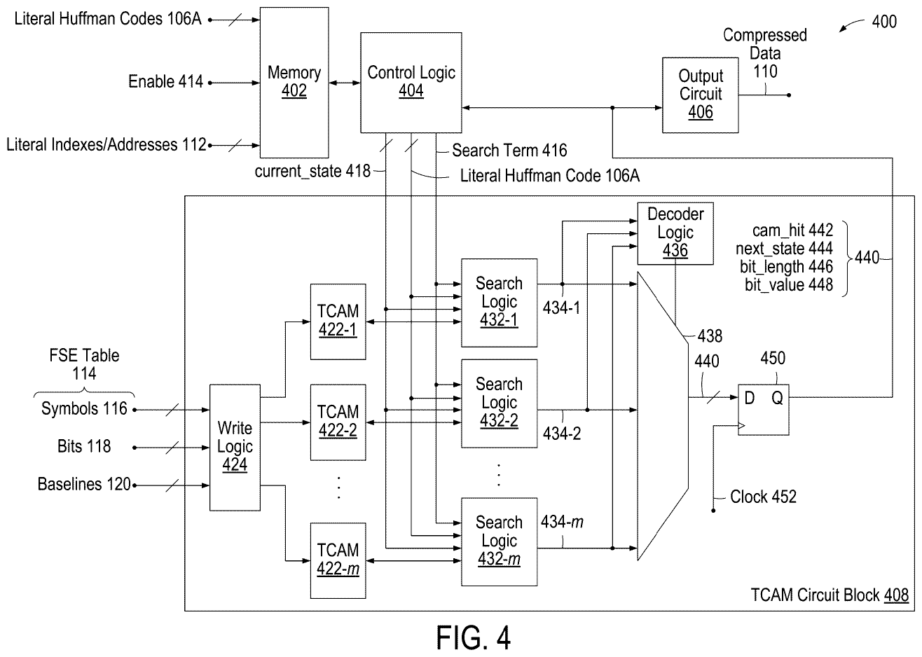

FIG. 4 depicts a TCAM-based encoder circuit 400, according to an embodiment. TCAM-based encoder circuit 400 may represent TCAM-based encoder circuit 108A or 108B. TCAM-based encoder circuit 400 is described below with respect to literals. Based on the description herein, one skilled in the relevant art(s) will understand how TCAM-based encoder circuit 400 functions with respect to sequences.

In the example of FIG. 4, TCAM-based encoder circuit 400 includes memory 402, control logic 404, an output circuit 406, and a TCAM circuit block 408. TCAM circuit block 408 receives FSE table 114 for a block of data 104. Memory 402 receives and stores literal Huffman codes 106A and literal indexes/addresses 112 for a block of data 104. Control logic 404 retrieves literal Huffman codes 106A and literal indexes/addresses 112 for a pair of literals from memory 402, and constructs a search term 416 based on current_state 418 and next literal symbol read out from memory 402. Control logic 404 outputs the search term 416, a literal Huffman code 106A, and a current_state 418 of an FSE table stored in TCAMs 422 as described below.

TCAM-based circuit block 408 includes multiple blocks of content addressable memory (CAM), depicted here as ternary CAMs (TCAMs) 422-1 through 422-m. (collectively, TCAMs 422). A CAM, also referred to as associative memory, compares input search data against a table of stored data, and returns the address of matching data. Binary CAM uses data search words consisting entirely of 1s and 0s. Ternary CAM permits a third matching state of don't care (i.e., X) for one or more bits in the stored data, thus adding flexibility to the search. For example, a stored word of 10XX0 in a TCAM will match any of the four search words 10000, 10010, 10100, or 10110. The added search flexibility comes at an additional cost over binary CAM as the internal memory cell must now encode three possible states instead of the two for the binary CAM. This additional state is typically implemented by adding a mask bit (care or don't care bit) to every memory cell.

In an example, and without limitation, TCAM circuit block 408 may include four TCAMs 422 having 16 entries each (i.e., for a total of 64 entries). TCAM-based encoder circuit 108B, may include, for example and without limitation, 32 TCAMs 422 (i.e., for a total of 512 entries). Where system 100 uses a single TCAM-based encoder circuit 108 to processes sequences and literals, TCAM circuit block 408 may use fewer TCAMs 422 when processing literals.

TCAM circuit block 408 further includes write logic 424 that writes FSE table 114 to TCAMs 422. In an example, write logic 424 writes entries of FSE table 114 (i.e., symbols 116, bits 118, and baselines 120) to respective entries of TCAMs 422.

TCAM circuit block 408 further includes search logic 432-1 through 432-m, (collectively, search logic 432) that search respective TCAMs 422 based on search term 416, the current_state 418 of the FSE table 114 stored in TCAMs 422, and literal Huffman code 106A. Search logic 432-1 through 432-m, output respective search results 434-1 through 434-m (collectively, search results 434).

Some search results 434 may include invalid/implausible search results. TCAM circuit block 408 further includes decoder logic 436 that selects search results 434 of one of TCAMs 422, and controls a multiplexer 438 to output the selected search results 434 as search results 440 (i.e., an encoded weight).

TCAM circuit block 408 further includes a latch (e.g., a transparent latch), depicted here as a D-type flip-flop (D-FF) 450, that outputs search result 440 when an enable control is active (e.g., pulled-up). In the example of FIG. 4, the enable control is depicted as a clock 452. In this example, D-FF 450 outputs selected search result 440 when clock 452 is high (e.g., on rising edges of clock 452).

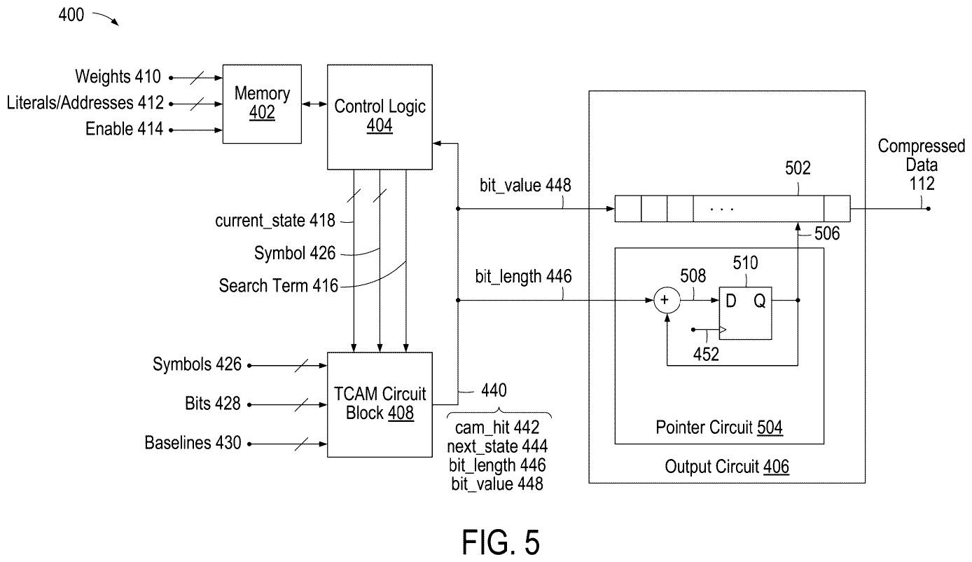

Search results 440 are provided to control logic 404, and to output circuit 406. Output circuit 406 is described below with reference to FIG. 5.

FIG. 5 depicts TCAM-based encoder circuit 400, according to an embodiment. In the example of FIG. 5, output circuit 406 includes a buffer 502 (e.g., a rolling or windowed buffer) that buffers bit_value 448 with other bit_values 448. Output circuit 406 further includes a pointer circuit 504 that determines a location at which to buffer bit_value 448 based on bit_length 446.

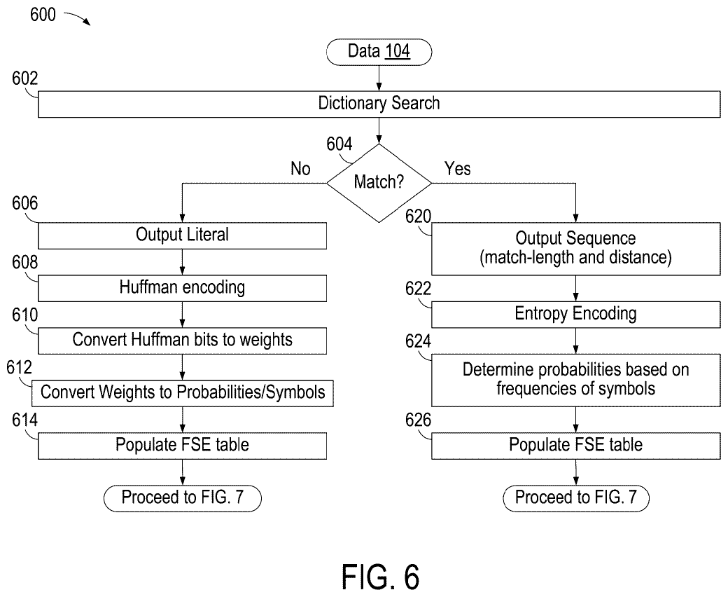

FIG. 6 depicts a method 600 of dictionary-based compression, according to an embodiment. Method 600 is described below with reference to FIGS. 1 through 5. Method 600 is not, however, limited to the examples of FIGS. 1 through 5.

At 602, dictionary encoder 202 performs a dictionary search for a segment of a data block 104.

At 604, if dictionary encoder 202 fails to find a matching string in dictionary 204, processing proceeds to 606 where dictionary encoder 202 outputs the segment of the data block 104 as a literal symbol 208.

At 608, Huffman encoder 218 converts literal symbols 208 to Huffman tree descriptions 220. Huffman encoding indicates how many bits are needed to represent literal symbols 208.

At 610, FSE compressor 222A converts Huffman bits to weights.

At 612, FSE compressor 222A converts the weights to probabilities.

At 614, FSE compressor 222A populates FSE table 114A with symbols 116A, bits 118A, and baselines 120A, based on the probabilities.

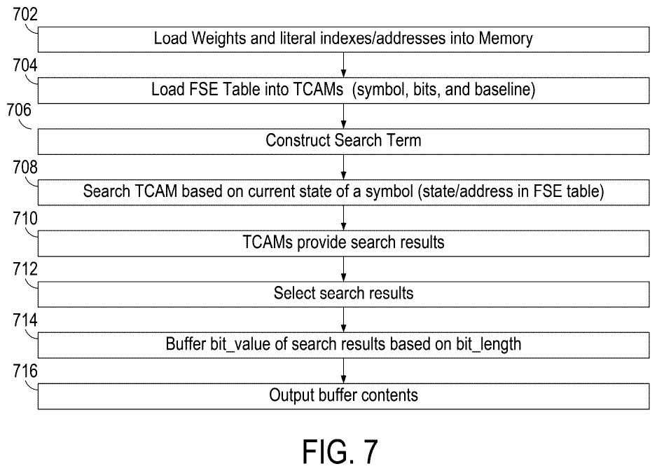

Processing then proceeds to FIG. 7, described further below.

Returning to 604, if dictionary encoder 202 finds a matching string in dictionary 204, processing proceeds to 620, where dictionary encoder 202 outputs a sequence 206 (i.e., a match-length and distance pair).

At 622, entropy encoder 210 encodes sequences 206 as weights or symbols 212.

At 624, FSE compressor 222B determines probabilities/symbols based on frequencies of weights/symbols 212.

At 626, FSE compressor 222B populates FSE table 114B with symbols 116B, bits 118B, and baselines 120B, based on the probabilities. Processing then proceeds to FIG. 7.

FIG. 7 depicts a method 700 of encoding weights based on FSE tables, according to an embodiment. Method 700 may be used to encode weights of sequences and/or weights of literals. Method 700 is described below with reference to literals.

At 702, memory 402 stores literal Huffman codes/sequence codes 106 and literal addresses 112 for literal symbols 208 of a block of data 104.

At 704, write logic 424 stores a corresponding FSE table 114A (i.e., symbols 116A, bits 118A, and baselines 120A) into TCAMs 422. Write logic 424 may write FSE table 114A in a top-to-bottom fashion.

At 706, control logic 404 constructs search term 416, and outputs the search term 416, the current_state 418 of FSE table 114A stored in TCAMs 422, and literal Huffman code 106A.

At 708, search logic 432-1 through 432-m search respective TCAMs 422 based on search term 416, current_state 418, and literal Huffman code 106A, and output respective search results 440.

At 710, TCAMs 422 provide respective results 434.

At 712, decoder logic 436 selects one of search results 434-1 through 434-m and controls multiplexer 438 to output the selected search results as search results 440. Search results 440 include the next state and the value to encode, and a length of the value (i.e., next_state 444, bit_value 448, and bit_length 446).

At 714, output circuit 406 buffers bit_value 448 in buffer 502, at a location determined by a pointer 506 that is controlled by a pointer circuit 504. In the example of FIG. 5, pointer circuit 504 increments pointer 506 based on bit_length 446 of the current literal symbol 208 to provide a new state 508. A D-FF 510 of pointer circuit 504 updates pointer 506 with new state 508 on a subsequent rising edge of clock 452 (i.e., when D-FF 450 outputs selected search results 440 for a subsequent literal).

At 716, when buffer 502 is full, output circuit 406 outputs contents of buffer 502 as compressed data 110. Compressed data may represent a frame (e.g., a Zstandard frame). Alternatively, compressed data 110 may be merged with other data (e.g., header information) to form a frame.

TCAM-based encoder 400 may implemented primarily and/or entirely with logic (e.g., combinational logic and/or sequential logic), such that TCAM-based encoder 400 outputs search results 440 for a pair of literals, every cycle of clock 452. As an example, where a block of data 104 has 256 literals, TCAM-based encoder 400 encodes the weights of the 256 literals over 256 cycles of clock 452.

A decompressor may decompress compressed data 110 based on known weights. The decompressor may rebuild the FSE table to determine the weights for the each literals. The decompressor may then determine the Huffman encoding from the weights. The decompressor may then decompress the literals based on the Huffman encoding.

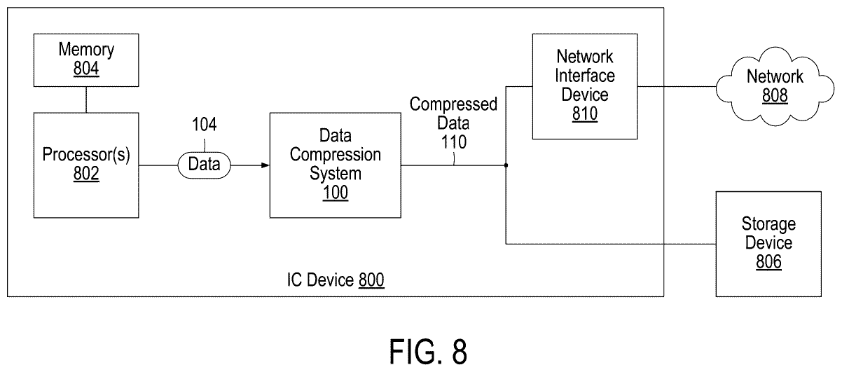

FIG. 8 depicts an integrated circuit (IC) device 800 that includes data compression system 100, according to an embodiment. IC device 800 further includes a processor(s) 802 and memory 804 encoded with instructions for execution by processor(s) 802. In the example of FIG. 8, data compression system 100 receives data 104 from processor, and outputs compressed data 110 to a storage device 806 and/or to a network 808 via a network interface device 810. IC device 800 may further include a data decompression system that receives compressed data from storage device 806 and/or from network 808, and decompresses the compressed data.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. An integrated circuit device, comprising:
a content addressable memory (CAM)-based encoder circuit, comprising:
multiple CAM circuits;
write logic configured to write entries of a finite state entropy (FSE) table to the CAM circuits, wherein each entry of the FSE table comprises a FSE state, a symbol, bits, and a baseline;
search logic configured to simultaneously search the CAM circuits based on a current state of the FSE table and the symbol, and to output results of the search, during a clock cycle;
decoder logic configured to select results of one of the CAM circuits based on the bits, the baseline, and the FSE states of the respective results, during the clock cycle; and
a latch configured to output the selected results in a subsequent clock cycle, wherein the selected results comprise an indication of a CAM hit, a next FSE table state, a bit value, and a length of the bit value.

2. The integrated circuit device of claim 1, wherein the CAM-based encoder circuit consists essentially of combinational logic, sequential logic, and random-access memory.

3. The integrated circuit device of claim 1, wherein the CAM circuits comprises ternary content-addressable memory (TCAM) circuits.

4. The integrated circuit device of claim 1, further comprising a dictionary-based compressor, comprising:
a dictionary encoder configured to search for matching sequences in a block of data and to output corresponding sequence symbols, and to output literal symbols for non-matching portions of the block of data;
a Huffman encoder configured to output Huffman tree descriptions of the literal symbols; and
a finite-state entropy (FSE) compressor configured to perform FSE compression on pairs of the Huffman tree descriptions of the literals to provide corresponding bits and baselines that specify jumps between the pairs of Huffman tree descriptions.

5. The integrated circuit device of claim 4, wherein the FSE compressor is further configured to:
convert numbers of Huffman bits of the Huffman tree descriptions to weights;
determine a probability distribution of the weights for the block of data; and
encode the probability distribution as the FSE table.

6. The integrated circuit device of claim 5, wherein the FSE compressor is further configured to:
normalize the probability distribution such that the weights are represented with fewer bits.

7. The integrated circuit device of claim 4, wherein the CAM-based encoder circuit further comprises:
random-access memory (RAM) configured to store the literal symbols and corresponding literal indexes for the block of data; and
control logic configured to,
read the literal symbols from the RAM in a reverse order,
construct a search term based on a current state and a next literal symbol read from the RAM, and
provide the search term, the next literal symbol, and a current FSE table state to the search logic;
wherein the search logic is further configured to traverse the FSE table stored in the CAM circuits based on the search term, the next literal symbol, and the current FSE table state.

8. The integrated circuit device of claim 1, wherein the CAM-based encoder circuit further comprises an output circuit configured to buffer the selected results of other literal symbols of the block of data.

9. A system, comprising:
a host processor and memory comprising instructions to cause the host processor to output data; and
a content-addressable memory (CAM)-based encoder circuit to compress the data, comprising:
multiple CAM circuits;
write logic configured to write entries of a finite state entropy (FSE) table to the CAM circuits, wherein each entry of the FSE table comprises a FSE state, a symbol, bits, and a baseline;
search logic configured to simultaneously search the CAM circuits based on a current state of the FSE table and the symbol, and to output results of the search, during a clock cycle;
decoder logic configured to select results of one of the CAM circuits based on the bits, the baseline, and the FSE states of the respective results, during the clock cycle; and
a latch configured to output the selected results in a subsequent clock cycle, wherein the selected results comprise an indication of a CAM hit, a next FSE table state, a bit value, and a length of the bit value.

10. The system of claim 9, wherein the CAM-based encoder circuit consists essentially of combinational logic, sequential logic, and random-access memory.

11. The system of claim 9, wherein the CAM circuits comprises ternary content-addressable memory (TCAM) circuits.

12. The system of claim 9, further comprising a dictionary-based compressor, comprising:
a dictionary encoder configured to search for matching sequences in a block of data and to output corresponding sequence symbols, and to output literal symbols for non-matching portions of the block of data;
a Huffman encoder configured to output Huffman tree descriptions of the literal symbols; and
a finite-state entropy (FSE) compressor configured to perform FSE compression on pairs of the Huffman tree descriptions of the literals to provide corresponding bits and baselines that specify jumps between the pairs of Huffman tree descriptions.

13. The system of claim 12, wherein the FSE compressor is further configured to:
convert numbers of Huffman bits of the Huffman tree descriptions to weights;
determine a probability distribution of the weights for the block of data; and
encode the probability distribution as the FSE table.

14. The system of claim 13, wherein the FSE compressor is further configured to:
normalize the probability distribution such that the weights are represented with fewer bits.

15. The system of claim 12, wherein the CAM-based encoder circuit further comprises:
random-access memory (RAM) configured to store the literal symbols and corresponding literal indexes for the block of data; and
control logic configured to,
read the literal symbols from the RAM in a reverse order,
construct a search term based on a current state and a next literal symbol read from the RAM, and
provide the search term, the next literal symbol, and a current FSE table state to the search logic;
wherein the search logic is further configured to traverse the FSE table stored in the CAM circuits based on the search term, the next literal symbol, and the current FSE table state.

16. The system of claim 9, wherein the CAM-based encoder circuit further comprises an output circuit configured to buffer the selected results of other literal symbols of the block of data.

17. A method, comprising:
writing entries of a finite state entropy (FSE) table to a set of content addressable memory (CAM) circuits, wherein each entry of the FSE table comprises a FSE state, a symbol, bits, and a baseline;
simultaneously searching the CAM circuits based on a current state of the FSE table and the symbol, and outputting results of the search, during a clock cycle;
selecting results of one of the CAM circuits based on the bits, the baseline, and the FSE states of the respective results, during the clock cycle; and
outputting the selected results in a subsequent clock cycle, wherein the selected results comprise an indication of a CAM hit, a next FSE table state, a bit value, and a length of the bit value.

18. The method of claim 17, further comprising:
searching for matching sequences in a block of data;
outputting sequence symbols for matching portions of the block of data, and outputting literal symbols for non-matching portions of the block of data;
generating Huffman tree descriptions of the literal symbols; and
performing finite-state entropy (FSE) compression on pairs of the Huffman tree descriptions of the literals to provide corresponding bits and baselines that specify jumps between the pairs of Huffman tree descriptions.

19. The method of claim 18, further comprising:
converting numbers of Huffman bits of the Huffman tree descriptions to weights;
determining a probability distribution of the weights for the block of data;
normalizing the probability distribution such that the weights are represented with fewer bits; and
encoding the normalized probability distribution as the FSE table.

20. The method of claim 18, further comprising:
storing the literal symbols and corresponding literal indexes for the block of data in random-access memory (RAM);
reading the literal symbols from the RAM in a reverse order; and
constructing a search term based on a current state and a next literal symbol read from the RAM;
wherein the simultaneously searching comprises traversing the FSE table stored in the CAM circuits based on the search term, the next literal symbol, and the current FSE table state.
